(19) United States
(12) Patent Application Publication
(10) Pub. No.: US 2016/0064528 A1
(43) Pub. Date: Mar. 3, 2016

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Chia-Lin Lu, Taoyuan County (TW); Chun-Lung Chen, Tainan City (TW); Kun-Yuan Liao, Hsin-Chu City (TW); Feng-Yi Chang, Tainan City (TW)

(21) Appl. No.: 14/509,070

(22) Filed: Oct. 8, 2014

(30) Foreign Application Priority Data
Aug. 27, 2014 (TW) 103129584

(51) Int. Cl. H01L 29/66; H01L 29/78

(52) U.S. Cl. CPC H01L 29/66795; H01L 29/785

(57) ABSTRACT

A method for fabricating semiconductor device is disclosed. The method includes the steps of: providing a substrate having a metal gate thereon and a hard mask atop the metal gate; and performing a high-density plasma (HDP) process to form a cap layer on the hard mask and the substrate.

### BACKGROUND OF THE INVENTION

1. Field of the Invention

The invention relates to a method for fabricating semiconductor device, and more particularly, to a method of using high-density plasma (HDP) deposition process to form cap layer on metal gates.

2. Description of the Prior Art

In current semiconductor industry, polysilicon has been widely used as a gap-filling material for fabricating gate electrode of metal-oxide-semiconductor (MOS) transistors. However, the conventional polysilicon gate also faced problems such as inferior performance due to boron penetration and unavoidable depletion effect which increases equivalent thickness of gate dielectric layer, reduces gate capacitance, and worsens driving force of the devices. In replacing polysilicon gates, work function metals have been developed to serve as a control electrode working in conjunction with high-K gate dielectric layers.

However, in current fabrication of high-k metal transistor, particularly during the stage when spacer is formed on the sidewall of gate structure, issues such as over-etching or undercut often arise and causing etching gas to etch through spacer until reaching the bottom of the gate structure. This induces erosion in high-k dielectric layer and/or bottom barrier metal (BBM) and affects the performance of the device substantially. Hence, how to resolve this issue has become an important task in this field.

### SUMMARY OF THE INVENTION

According to a preferred embodiment of the present invention, a method for fabricating semiconductor device is disclosed. The method includes the steps of: providing a substrate having a metal gate thereon and a hard mask atop the metal gate; and performing a high-density plasma (HDP) process to form a cap layer on the hard mask and the substrate.

According to another aspect of the present invention, a semiconductor device is disclosed. The semiconductor device includes: a substrate; a metal gate on the substrate; a source/drain region adjacent to the metal gate in the substrate; and a triangular cap layer on the metal gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-4 illustrate a method for fabricating semiconductor device according to a preferred embodiment of the present invention.

### DETAILED DESCRIPTION

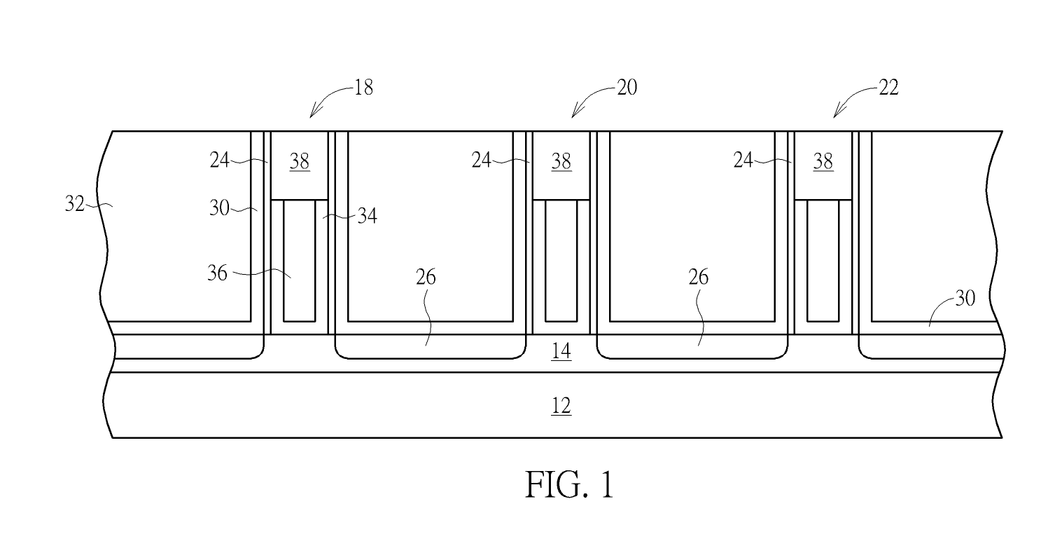

Referring to FIGS. 1-4, FIGS. 1-4 illustrate a method for fabricating semiconductor device according to a preferred embodiment of the present invention. As shown in FIG. 1, a substrate 12, such as a silicon substrate or silicon-on-insulator (SOI) substrate is provided, and a transistor region, such as a PMOS region or a NMOS region is defined on the substrate 12.

At least a first fin-shaped structure 14 and an insulating layer (not shown) are formed on the substrate 12, in which the bottom of the fin-shapes structure 14 is preferably enclosed by the insulating layer, such as silicon oxide to form a shallow trench isolation (STI). A plurality of metal gates 18, 20, 22 are formed on part of the fin-shaped structure 14. It should be noted that even though only three metal gates are disclosed in this embodiment, the quantity of the metal gates is not limited to three, but could by any quantity depending on the demand of the product.

The formation of the fin-shaped structure 14 could be accomplished by first forming a patterned mask (now shown) on the substrate, 12, and an etching process is performed to transfer the pattern of the patterned mask to the substrate 12. Next, depending on the structural difference of a tri-gate transistor or dual-gate fin-shaped transistor being fabricated, the patterned mask could be stripped selectively or retained, and deposition, chemical mechanical polishing (CMP), and etching back processes are carried out to form an insulating layer surrounding the bottom of the fin-shaped structure 14. Alternatively, the formation of the fin-shaped structure 14 could also be accomplished by first forming a patterned hard mask (not shown) on the substrate 12, and then performing an epitaxial process on the exposed substrate 12 through the patterned hard mask to grow a semiconductor layer. This semiconductor layer could then be used as the corresponding fin-shaped structure 14. In another fashion, the patterned hard mask could be removed selectively or retained, and deposition, CMP, and then etching back could be used to form an insulating layer to surround the bottom of the fin-shaped structure 14. Moreover, if the substrate 12 were a SOI substrate, a patterned mask could be used to etch a semiconductor layer on the substrate until reaching a bottom oxide layer underneath the semiconductor layer to form the corresponding fin-shaped structure. If this means is chosen the aforementioned steps for fabricating the insulating layer could be eliminated.

The fabrication of the metal gates 18, 20, 22 could be accomplished by a gate first process, a high-k first approach from gate last process, or a high-k last approach from gate last process. Since this embodiment pertains to a high-k first approach, dummy gates (not shown) composed of high-k dielectric layer and polysilicon material could be first formed on the fin-shaped structure 14 and the insulating layer, and a spacer 24 is formed on the sidewall of the dummy gates. A source/drain region 26 and epitaxial layer (not shown) are then formed in the fin-shaped structure 14 and/or substrate 12 adjacent to two sides of the spacer 24, a contact etch stop layer (CESL) 30 is formed on the dummy gates, and an interlayer dielectric (ILD) layer (not shown) composed of tetraethyl orthosilicate (TEOS) is formed on the CESL 30.

Next, a replacement metal gate (RMG) process could be conducted to planarize part of the ILD layer 32 and CESL 30 and then transforming the dummy gate into metal gates. The RMG process could be accomplished by first performing a selective dry etching or wet etching process, such as using etchants including ammonium hydroxide (NH₄OH) or tetramethylammonium hydroxide (TMAH) to remove the polysilicon layer from dummy gates for forming a recess (not shown) in the ILD layer 32. Next, a conductive layer including at least a U-shaped work function metal layer 34 and a low resistance metal layer 36 is formed in the recess, and a planarizing process is conducted so that the surface of the U-shaped work function layer 34 and low resistance metal layer 36 is even with the surface of the ILD layer 32.

In this embodiment, the work function metal layer 34 is formed for tuning the work function of the later formed metal gates to be appropriate in an NMOS or a PMOS. For an NMOS transistor, the work function metal layer 34 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 34 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 34 and the low resistance metal layer 36, in which the material of the barrier layer may include titanium (Ti), titanium nitride (TiN), tantalum (Ta) or tantalum nitride (TaN). Furthermore, the material of the low-resistance metal layer 36 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity.

After forming the metal gates 18, 20, 22, part of the work function metal layer 34 and low resistance metal layer 36 could be removed, and a hard mask 38 is formed on the work function metal layer 34 and the low resistance metal layer 36. The hard mask 38 could be a single material layer or composite material layer, such as a composite layer containing both silicon oxide and silicon nitride.

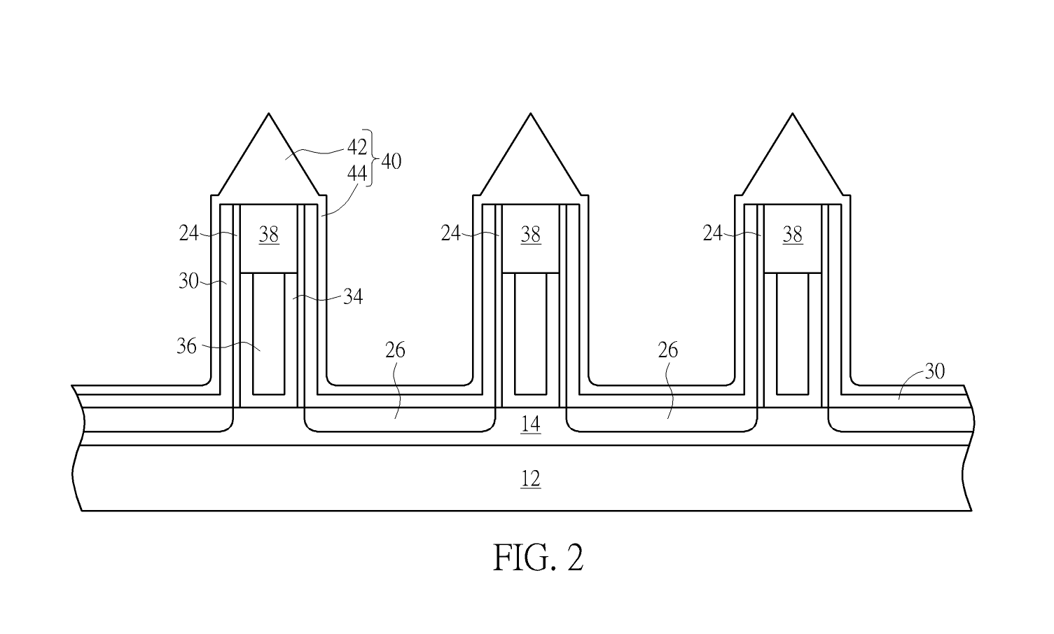

Next, as shown in FIG. 2, the entire ILD layer 32 is removed to expose the metal gates 18, 20, 22 and the CESL 30, and a high-density plasma (HDP) deposition process is conducted to form a cap layer 40 on the hard mask 38 and the CESL 30. Since a standard HDP process typically involves deposition and etching features simultaneously, such as depositing a dielectric material composed of silicon nitride while removing corner dielectric materials constantly and continuously, the cap layer 40 being fabricated through HDP process of this embodiment preferably includes a triangular cap layer 42 directly on top of the hard mask 38 and a cap layer 44 under part of the triangular cap layer 42 and covering the CESL 30 on sidewalls of the metal gates 18, 20, 22 and the CESL 30 on the substrate 12. In this embodiment, the triangular cap layer 42 and the cap layer 44 are both composed of silicon nitride, but not limited thereto.

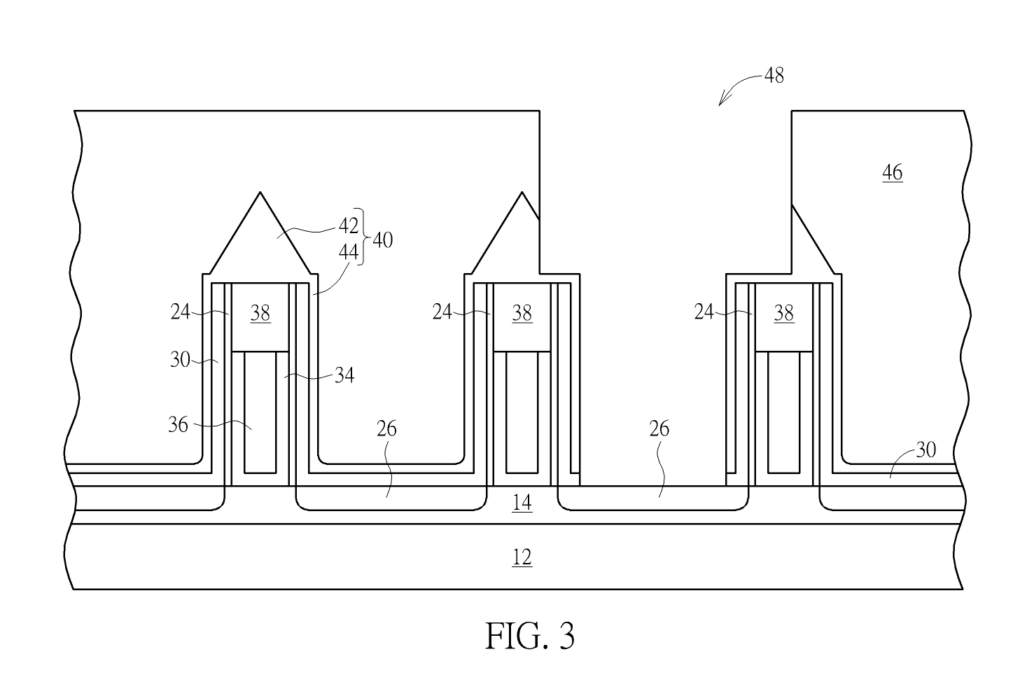

Next, as shown in FIG. 3, another ILD layer 46 is formed on the cap layer 40 and the substrate 12, and a photo-etching process is conducted by using a patterned resist (not shown) as mask to remove part of the ILD layer 46, part of the triangular cap layer 42, and part of the CESL 30 through single or multiple etching processes to form a contact hole 48 adjacent to the metal gate 20.

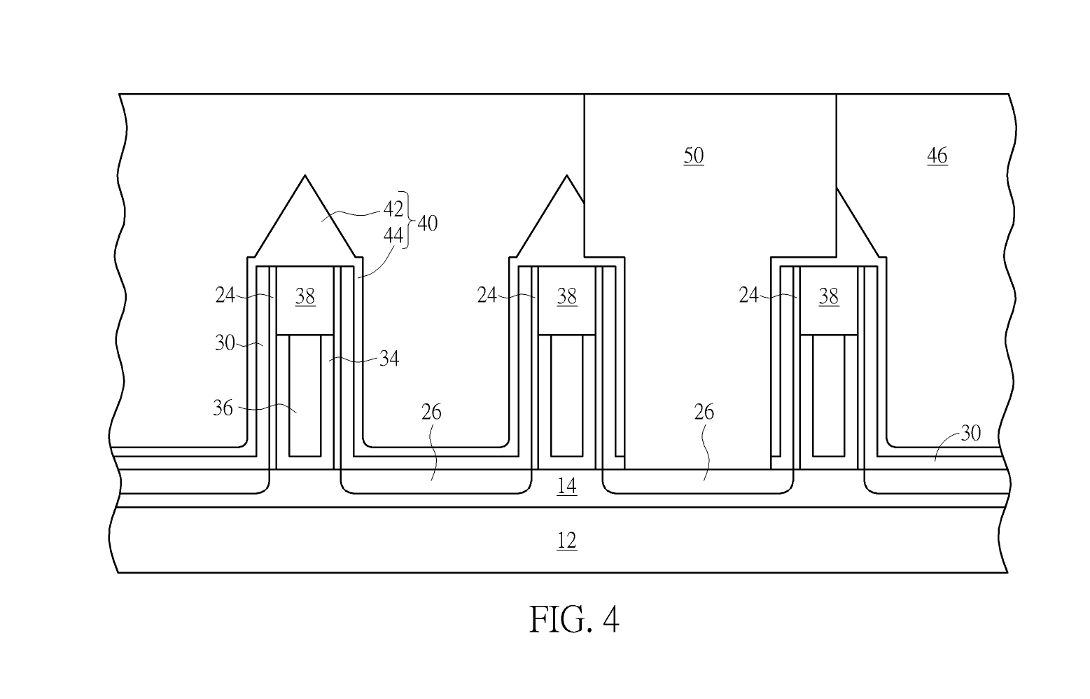

Next, as shown in FIG. 4, metal material could be deposited into the contact hole 48 and a planarizing process is conducted thereafter to remove part of the metal material for forming contact plug 50. Since the fabrication of contact plugs is well known to those skilled in the art, the details of which is not explained herein for the sake of brevity. This completes the fabrication of a semiconductor device according to a preferred embodiment of the present invention.

Referring again to FIG. 2, which further illustrates a structural view of a semiconductor device according to a preferred embodiment of the present invention. As shown in FIG. 2, the semiconductor device includes a substrate 12, a plurality of metal gates 18, 20, 22 disposed on the substrate 12, a plurality of source/drain regions 26 in the substrate 12 adjacent to two sides of the metal gates 18, 20, 22, a triangular cap layer 42 on the metal gates 18, 20, 22, and a hard mask 38 between the triangular cap layer 42 and the metal gates 18, 20, 22.

A CESL 30 is disposed on the sidewalls of the hard mask 38 and metal gates 18, 20, 22 and on the substrate 12, and another cap layer 44 is disposed under the triangular cap layer 42 and on the surface of the CESL 30. The CESL 30 and the hard mask 38 are preferably composed of silicon nitride, but not limited thereto, and the triangular cap layer 42 and cap layer 44 are also composed of silicon nitride, but not limited thereto.

Overall, the present invention preferably conducts a high-density plasma (HDP) process after the formation of metal gates and hard mask thereon to form a substantially triangular cap layer on the hard mask and another cap layer on the sidewalls of the metal gates. According to a preferred embodiment of the present invention, the triangular cap layer formed through HDP process is utilized as a layer of protection for the metal gates in addition to the hard mask 38, so that damages to the metal gates caused by etchant used during self-aligned contact (SAC) process thereafter could be minimized.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating semiconductor device, comprising:
providing a substrate having a metal gate thereon and a hard mask atop the metal gate; and
performing a high-density plasma (HDP) process to form a cap layer on the hard mask and the substrate.

2. The method of claim 1, further comprising:
forming a fin-shaped structure on the substrate; and
forming the metal gate on the fin-shaped structure.

3. The method of claim 1, wherein the hard mask comprises silicon nitride.

4. The method of claim 1, wherein the cap layer comprises silicon nitride.

5. The method of claim 1, wherein the cap layer comprises a rectangular cap layer atop the hard mask.

6. The method of claim 1, further comprising a contact etch stop layer (CESL) adjacent to the sidewalls of the hard mask and the metal gate and on the substrate.

7. The method of claim 6, further comprising performing the HDP process for forming the cap layer on the CESL.

8. The method of claim 1, further comprising forming an interlayer dielectric (ILD) layer on the cap layer and the substrate.

9. The method of claim 8, further comprising removing part of the ILD layer and part of the cap layer for forming a contact hole adjacent to the metal gate.

10. A semiconductor device, comprising:
a substrate;
a metal gate on the substrate;
a source/drain region adjacent to the metal gate in the substrate; and
a triangular cap layer on the metal gate.

11. The semiconductor device of claim 10, further comprising:
a fin-shaped structure on the substrate; and
the metal gate on the fin-shaped structure.

12. The semiconductor device of claim 10, wherein the triangular cap layer comprises silicon nitride.

13. The semiconductor device of claim 10, further comprising a hard mask between the triangular cap layer and the metal gate.

14. The semiconductor device of claim 13, wherein the hard mask comprises silicon nitride.

15. The semiconductor device of claim 13, further comprising a contact etch stop layer (CESL) adjacent to the sidewalls of the hard mask and the metal gate and on the substrate.

16. The semiconductor device of claim 15, further comprising a cap layer under part of the triangular cap layer and on the CESL.

17. The semiconductor device of claim 10, wherein the cap layer and the triangular cap layer comprise same material.
